(19) United States
(12) Patent Application Publication
(10) Pub. No.: US 2019/0051818 A1
(43) Pub. Date: Feb. 14, 2019

(54) MAGNETIC MEMORY ELEMENT AND MAGNETIC MEMORY DEVICE

(71) Applicant: Kabushiki Kaisha Toshiba, Minato-ku (JP)

(72) Inventors: Soichi OIKAWA, Hachioji (JP); Yushi Kato, Chofu (JP); Mizue Ishikawa, Yokohama (JP); Yoshiaki Saito, Kawasaki (JP); Hiroaki Yoda, Kawasaki (JP)

(73) Assignee: Kabushiki Kaisha Toshiba, Minato-ku (JP)

(21) Appl. No.: 15/897,255

(22) Filed: Feb. 15, 2018

(30) Foreign Application Priority Data
Aug. 8, 2017 (JP) 2017-153600

(51) Int. Cl. H01L 43/08; G11C 11/16; H01L 43/10; H01L 27/22

(52) U.S. Cl. CPC H01L 43/08; G11C 11/161; H01L 27/228; G11C 11/1673; H01L 43/10

(57) ABSTRACT

According to one embodiment, a magnetic memory element includes a conductive layer, a first magnetic layer, a second magnetic layer, and a first nonmagnetic layer. The first magnetic layer is separated from the conductive layer. The second magnetic layer includes iron, platinum, and boron and is provided between the conductive layer and the first magnetic layer. The first nonmagnetic layer is provided between the first magnetic layer and the second magnetic layer. The conductive layer includes a first region and a second region. The second region includes a first metal and boron and is provided between the first region and the second magnetic layer. The first region does not include boron, or a first concentration of boron in the first region is lower than a second concentration of boron in the second region.

### CROSS-REFERENCE TO RELATED APPLICATIONS

This application is based upon and claims the benefit of priority from Japanese Patent Application No. 2017-153600, filed on Aug. 8, 2017; the entire contents of which are incorporated herein by reference.

### FIELD

Embodiments described herein relate generally to a magnetic memory element and a magnetic memory device.

### BACKGROUND

There is a magnetic memory element that uses a magnetic layer. A magnetic memory device is formed from the magnetic memory element. Stable operations of the magnetic memory element and the magnetic memory device are desirable.

### BRIEF DESCRIPTION OF THE DRAWINGS

FIG. 1 is a schematic perspective view illustrating a magnetic memory device according to a first embodiment;

FIG. 2 is a schematic cross-sectional view illustrating the magnetic memory device according to the first embodiment;

FIG. 3 is a schematic cross-sectional view illustrating the sample of the experiment relating to the magnetic memory device;

FIG. 4 is a schematic cross-sectional view illustrating a sample of the experiment relating to the magnetic memory device;

FIG. 5 is a graph illustrating experimental results relating to the magnetic memory device;

FIG. 6 is a graph illustrating experimental results relating to the magnetic memory device;

FIG. 7 is a graph illustrating experimental results relating to the magnetic memory device;

FIG. 8A to FIG. 8D are schematic cross-sectional views illustrating samples of the experiment relating to the magnetic memory device;

FIG. 9 is a graph illustrating the experimental results relating to the magnetic memory device;

FIG. 10 is a schematic perspective view illustrating another magnetic memory device according to the first embodiment;

FIG. 11 is a schematic perspective view illustrating a magnetic memory device according to a second embodiment;

FIG. 12A to FIG. 12C are schematic perspective views illustrating a magnetic memory device according to a third embodiment; and

FIG. 13 is a schematic view showing a magnetic memory device according to a fourth embodiment.

### DETAILED DESCRIPTION

According to one embodiment, a magnetic memory element includes a conductive layer, a first magnetic layer, a second magnetic layer, and a first nonmagnetic layer. The first magnetic layer is separated from the conductive layer. The second magnetic layer includes iron, platinum, and boron and is provided between the conductive layer and the first magnetic layer. The first nonmagnetic layer is provided between the first magnetic layer and the second magnetic layer. The conductive layer includes a first region and a second region. The second region includes a first metal and boron and is provided between the first region and the second magnetic layer. The first region does not include boron, or a first concentration of boron in the first region is lower than a second concentration of boron in the second region.

According to another embodiment, a magnetic memory device includes a magnetic memory element and a controller. The magnetic memory element includes a conductive layer, a first magnetic layer, a second magnetic layer, and a first nonmagnetic layer. The first magnetic layer is separated from the conductive layer. The second magnetic layer includes iron, platinum, and boron and is provided between the conductive layer and the first magnetic layer. The first nonmagnetic layer is provided between the first magnetic layer and the second magnetic layer. The conductive layer includes a first region and a second region. The second region includes a first metal and boron and is provided between the first region and the second magnetic layer. The first region does not include boron, or a first concentration of boron in the first region is lower than a second concentration of boron in the second region. The conductive layer includes a first portion, a second portion and a third portion between the first portion and the second portion. The first magnetic layer is separated from the third portion in a first direction crossing a second direction. The second direction is from the first portion toward the second portion. The second magnetic layer is provided between the third portion and the first magnetic layer. The controller is electrically connected to the first portion and the second portion. The controller is configured to implement a first operation of supplying a first current to the conductive layer from the first portion toward the second portion, and a second operation of supplying a second current to the conductive layer from the second portion toward the first portion.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

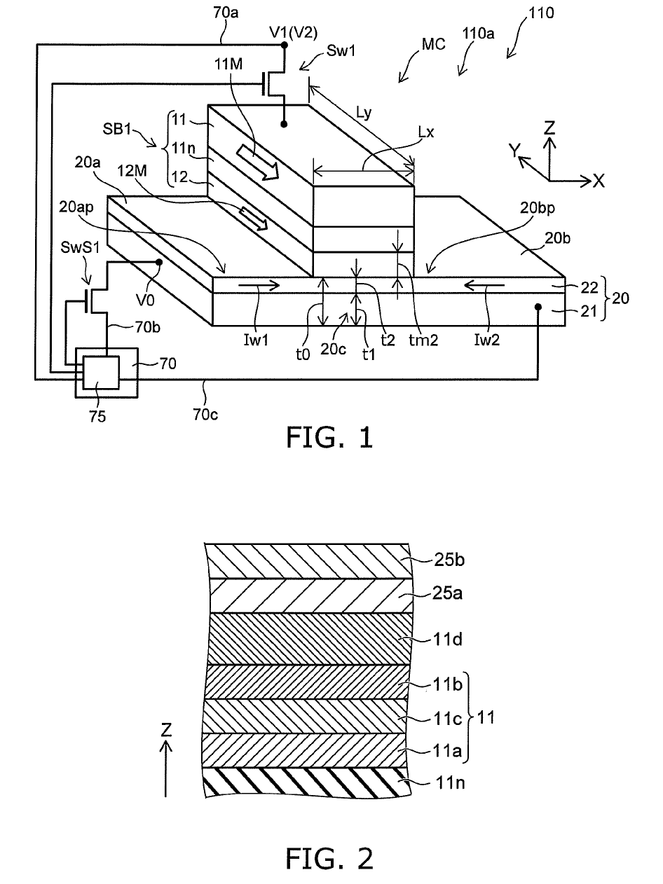

FIG. 1 is a schematic perspective view illustrating a magnetic memory device according to a first embodiment.

As shown in FIG. 1, the magnetic memory device 110 according to the embodiment includes a conductive layer 20, a first magnetic layer 11, a second magnetic layer 12, a first nonmagnetic layer 11n, and a controller 70. A magnetic memory element 110a according to the embodiment includes the conductive layer 20, the first magnetic layer 11, the second magnetic layer 12, and the first nonmagnetic layer 11n. The magnetic memory element 110a may be included in the magnetic memory device 110.

The conductive layer 20 includes a first portion 20a, a second portion 20b, and a third portion 20c. The third portion 20c is positioned between the first portion 20a and the second portion 20b.

The first magnetic layer 11 is separated from the third portion 20c in a first direction. The first direction crosses a second direction from the first portion 20a toward the second portion 20b.

The first direction is taken as a Z-axis direction. One direction perpendicular to the Z-axis direction is taken as an X-axis direction. A direction perpendicular to the Z-axis direction and the X-axis direction is taken as a Y-axis direction. In the example, the second direction is the X-axis direction.

The second magnetic layer 12 is provided between the third portion 20c and the first magnetic layer 11. The first nonmagnetic layer 11n is provided between the first magnetic layer 11 and the second magnetic layer 12. Another layer may be provided between the first nonmagnetic layer 11n and the first magnetic layer 11. Another layer may be provided between the first nonmagnetic layer 11n and the second magnetic layer 12.

The first magnetic layer 11 functions as, for example, a reference layer. The second magnetic layer 12 functions as, for example, a memory layer (e.g., a free layer). A second magnetization 12M of the second magnetic layer 12 changes more easily than a first magnetization 11M of the first magnetic layer 11. The orientation of the second magnetization 12M of the second magnetic layer 12 corresponds to information that is stored. For example, the orientation of the magnetization corresponds to the orientation of the easy magnetization axis.

The first magnetic layer 11, the first nonmagnetic layer 11n, and the second magnetic layer 12 are included in a first stacked body SB1. The first stacked body SB1 functions as, for example, at least a portion of one memory cell MC. The first stacked body SB1 has, for example, a magnetic tunnel junction (MTJ). The first stacked body SB1 corresponds to a MTJ element.

In the example, a length Ly along a third direction of the first magnetic layer 11 is longer than a length Lx along the second direction of the first magnetic layer 11. The third direction crosses a plane including the first direction and the second direction. The third direction is, for example, the Y-axis direction. Shape anisotropy occurs in the first magnetic layer 11 and the second magnetic layer 12. For example, the first magnetization 11M of the first magnetic layer 11 is aligned with the Y-axis direction. For example, the second magnetization 12M of the second magnetic layer 12 is oriented in the +Y direction or the −Y direction. In the embodiment, the relationship between the length Ly and the length Lx is arbitrary.

In the embodiment, the first magnetic layer 11 is, for example, an in-plane magnetization film. For example, the first magnetization 11M of the first magnetic layer 11 crosses the first direction (the Z-axis direction). In the example, the first magnetization 11M of the first magnetic layer 11 is aligned with the third direction (e.g., the Y-axis direction, i.e., a direction crossing a plane including the first direction and the second direction). For example, the orientation of the first magnetization 11M in the X-Y plane is arbitrary.

In the embodiment, the second magnetic layer 12 is, for example, an in-plane magnetization film. For example, the second magnetization 12M of the second magnetic layer 12 crosses the first direction (the Z-axis direction). In the example, the second magnetization 12M of the second magnetic layer 12 is aligned with the third direction recited above. For example, the orientation of the second magnetization 12M in the X-Y plane is arbitrary.

The controller 70 is electrically connected to the first portion 20a and the second portion 20b. In the example, the controller 70 includes a control circuit 75. The control circuit 75 (the controller 70) and the first portion 20a are electrically connected by an interconnect 70b. The control circuit 75 (the controller 70) and the second portion 20b are electrically connected by an interconnect 70c. In the example, a switch SwS1 is provided in a current path (the interconnect 70b) between the control circuit 75 and the first portion 20a. The gate (the control terminal) of the switch SwS1 is electrically connected to the control circuit 75.

In the example, the control circuit 75 (the controller 70) is electrically connected to the first magnetic layer 11. The control circuit 75 (the controller 70) and the first magnetic layer 11 are electrically connected by an interconnect 70a. In the example, a switch Sw1 is provided in a current path (the interconnect 70a) between the control circuit 75 and the first magnetic layer 11. The gate (the control terminal) of the switch Sw1 is electrically connected to the control circuit 75.

These switches may be included in the controller 70. The potentials of the conductive layer 20 and the first stacked body SB1 are controlled by the controller 70. For example, the first portion 20a is set to a reference potential V0; and a first voltage V1 (e.g., a select voltage) is applied to the first magnetic layer 11. At this time, for example, the electrical resistance of the first stacked body SB1 changes according to the orientation of the current flowing in the conductive layer 20. On the other hand, the first portion 20a is set to the reference potential V0; and a second voltage V2 (e.g., an unselect voltage) is applied to the first magnetic layer 11. The second voltage V2 is different from the first voltage V1. When the second voltage V2 is applied, for example, the electrical resistance of the first stacked body SB1 substantially does not change even in the case where a current flows in the conductive layer 20. The change of the electrical resistance corresponds to the change of the state of the first stacked body SB1. For example, the change of the electrical resistance corresponds to the change of the orientation of the second magnetization 12M of the second magnetic layer 12.

For example, the second voltage V2 is different from the first voltage V1. For example, the absolute value of the potential difference between the reference potential V0 and the first voltage V1 is greater than the absolute value of the potential difference between the reference potential V0 and the second voltage V2. For example, the polarity of the first voltage V1 may be different from the polarity of the second voltage V2. Such an electrical resistance difference is obtained by a control of the controller 70.

For example, the controller 70 performs a first operation and a second operation. These operations are operations when the select voltage is applied to the stacked body SB1. In the first operation, the controller 70 supplies a first current Iw1 to the conductive layer 20 from the first portion 20a toward the second portion 20b (referring to FIG. 1). In the second operation, the controller 70 supplies a second current Iw2 to the conductive layer 20 from the second portion 20b toward the first portion 20a (referring to FIG. 1).

The first electrical resistance between the first magnetic layer 11 and the first portion 20a after the first operation is different from the second electrical resistance between the first magnetic layer 11 and the first portion 20a after the second operation. For example, such an electrical resistance difference corresponds to the change of the orientation of the second magnetization 12M of the second magnetic layer 12.

For example, the orientation of the second magnetization 12M changes due to the current (a program current) flowing through the conductive layer 20. For example, it is considered that this is based on the spin Hall effect. For example, it is considered that the change of the orientation of the second magnetization 12M is based on spin-orbit coupling.

For example, due to the first operation, the second magnetization 12M has a component having the same orientation as the orientation of the first magnetization 11M. A “parallel” magnetization is obtained. On the other hand, due to the second operation, the second magnetization 12M has a component having the reverse orientation of the orientation of the first magnetization 11M. An “antiparallel” magnetization is obtained. In such a case, the first electrical resistance after the first operation is lower than the second electrical resistance after the second operation. Such an electrical resistance difference corresponds to the information to be stored. For example, the different multiple magnetizations correspond to the information to be stored.

For example, a first memory state is formed in the memory cell MC by the first operation. A second memory state is formed in the memory cell MC by the second operation. For example, the first memory state corresponds to one piece of information of “0” or “1.” The second memory state corresponds to the other information of “0” or “1.” For example, the first operation corresponds to a first program operation. For example, the second operation corresponds to a second program operation. The first operation may be one of a “program operation” or an “erase operation;” and the second operation may be the other of the “program operation” or the “erase operation.” For example, in the case where multiple memory cells MC are provided, these operations correspond to the program operation of the selected memory cell MC (the first stacked body SB1).

The controller 70 may further implement a third operation and a fourth operation. The third operation and the fourth operation correspond to operations of an unselected memory cell MC (e.g., the first stacked body SB1). For example, in the third operation and the fourth operation, the memory state of the unselected memory cell MC (e.g., the first stacked body SB1) substantially is not changed. For example, in the third operation, the potential difference between the first portion 20a and the first magnetic layer 11 is set to the second voltage V2; and the first current Iw1 is supplied to the conductive layer 20. In the fourth operation, the potential difference between the first portion 20a and the first magnetic layer 11 is set to the second voltage V2; and the second current Iw2 is supplied to the conductive layer 20. In the third operation and the fourth operation, for example, the electrical resistance of the first stacked body SB1 substantially does not change even in the case where a current flows in the conductive layer 20. A first electrical resistance between the first magnetic layer 11 and the first portion 20a after the first operation is different from a second electrical resistance between the first magnetic layer 11 and the first portion 20a after the second operation. The absolute value of the difference between the first electrical resistance and the second electrical resistance is greater than the absolute value of the difference between a third electrical resistance between the first magnetic layer 11 and the first portion 20a after the third operation and a fourth electrical resistance between the first magnetic layer 11 and the first portion 20a after the fourth operation. The memory state of the memory cell MC (e.g., the first stacked body SB1) substantially does not change before and after the third operation. The memory state of the memory cell MC (e.g., the first stacked body SB1) substantially does not change before and after the fourth operation.

In the magnetic memory device 110 according to the embodiment, a portion of the conductive layer 20 includes boron (B).

For example, the third portion 20c includes a first region 21 and a second region 22. The second region 22 is provided between the first region 21 and the second magnetic layer 12. For example, the second region 22 physically contacts the second magnetic layer 12. The second region 22 includes a first metal and boron.

In the example, the first region 21 extends along the second direction (e.g., the X-axis direction) between the first portion 20a and the second portion 20b. The second region 22 extends along the second direction between the first portion 20a and the second portion 20b.

The first metal includes at least one selected from the group consisting of Ta, W, Re, Os, Ir, Pt, Au, Cu, Ag, and Pd. Thereby, for example, the spin Hall effect is obtained effectively.

The second region 22 includes boron and at least one selected from the group consisting of Ta, W, Re, Os, Ir, Pt, Au, Cu, Ag, and Pd. The second region 22 may include, for example, at least one selected from the group consisting of TaB, WB, ReB, OsB, IrB, PtB, AuB, CuB, AgB, and PdB.

On the other hand, the first region 21 does not include boron. Or, the first region 21 includes boron; and a first concentration of boron in the first region 21 is lower than a second concentration of boron in the second region 22. The first region 21 includes, for example, a first metal.

For example, a thickness DL of the magnetic dead layer decreases when the second concentration of boron in the second region 22 is 10 atm % or more. For example, the thickness DL is substantially constant for a second concentration of 10 atm % or more.

It is favorable for the second concentration of boron in the second region 22 to be not less than 10 atm % and not more than 50 atm %. For example, a large effective perpendicular anisotropic magnetic field Hk_eff is obtained for such a concentration. It is more favorable for the second concentration of boron in the second region 22 to be not less than 10 atm % and not more than 30 atm %. In such a case, for example, a saturation magnetization Ms of the second magnetic layer 12 is small.

In the embodiment, the second region 22 may be provided locally at a position overlapping the first stacked body SB1 in the Z-axis direction. For example, the second region 22 may not include a portion not overlapping the second magnetic layer 12 in the Z-axis direction. For example, the first portion 20a includes a first non-overlap region 20ap (referring to FIG. 1). For example, the second portion 20b includes a second non-overlap region 20bp (referring to FIG. 1). The first non-overlap region 20ap and the second non-overlap region 20bp do not overlap the second magnetic layer 12 in the first direction (the Z-axis direction). At least one of these non-overlap regions may not include boron. Or, the concentration of boron in at least one of these non-overlap regions may be lower than the second concentration.

In the embodiment, a thickness t0 of the conductive layer 20 is, for example, not less than 2 nanometers (nm) and not more than 11 nm. On the other hand, a thickness tm2 of the second magnetic layer 12 is not less than 0.5 nanometers and not more than 3 nanometers. Lattice mismatch occurs effectively when these layers are in the appropriate range. The lattice relaxes easily when the thickness is excessively thick.

A thickness t1 of the first region 21 of the conductive layer 20 is, for example, not less than 1 nm and not more than 7 nm. A thickness t2 of the second region 22 is, for example, not less than 1 nm and not more than 7 nm.

The thickness tm2 of the second magnetic layer 12 is, for example, not less than 0.6 nm and not more than 6 nm.

In the description recited above, the thickness is the length along the first direction (the Z-axis direction).

FIG. 2 is a schematic cross-sectional view illustrating the magnetic memory device according to the first embodiment.

FIG. 2 illustrates a portion of the first stacked body SB1. In one example as shown in FIG. 2, the first magnetic layer 11 includes a first magnetic film 11a, a second magnetic film 11b, and a nonmagnetic film 11c. The first magnetic film 11a is positioned between the second magnetic film 11b and the first nonmagnetic layer 11n. The nonmagnetic film 11c is positioned between the first magnetic film 11a and the second magnetic film 11b. The first magnetic film 11a is, for example, a CoFeB film. The thickness of the first magnetic film 11a is, for example, not less than 1.2 nm and not more than 2.4 nm (e.g., about 1.8 nm). The second magnetic film 11b is, for example, a CoFeB film. The thickness of the second magnetic film 11b is, for example, not less than 1.2 nm and not more than 2.4 nm (e.g., about 1.8 nm). The nonmagnetic film 11c is, for example, a Ru film. The thickness of the nonmagnetic film 11c is, for example, not less than 0.7 nm and not more than 1.1 nm.

In the example, the first stacked body SB1 further includes an IrMn-layer 11d. The first magnetic layer 11 is positioned between the IrMn-layer 11d and the first nonmagnetic layer 11n. The thickness of the IrMn-layer 11d is, for example, not less than 5 nm and not more than 12 nm (e.g., 8 nm). In the example, the first stacked body SB1 further includes a Ta film 25a and a Ru film 25b. In one example, the thickness of the Ta film 25a is not less than 3 nm and not more than 7 nm (e.g., 5 nm). In one example, the thickness of the Ru film 25b is not less than 5 nm and not more than 10 nm (e.g., about 7 nm).

In the embodiment, the second magnetic layer 12 includes Fe (iron), Pt (platinum), and B. The second magnetic layer 12 may further include Co. For example, Pt is dispersed in the second magnetic layer 12. For example, the region that includes Pt may not have a layer configuration. For example, B is dispersed in the second magnetic layer 12. For example, the region that includes B may not have a layer configuration.

It was found that a large voltage effect (field effect) is obtained by providing the conductive layer 20 including the first region 21 and the second region 22 such as that recited above and the second magnetic layer 12 such as that recited above. Thereby, for example, the state of the first stacked body SB1 (the memory cell MC) can be controlled easily. Thereby, a magnetic memory device can be provided in which stable operations are possible. The voltage effect is, for example, the effect of the magnetic anisotropy control by a voltage or an electric field.

Experimental results relating to the magnetic memory device will now be described.

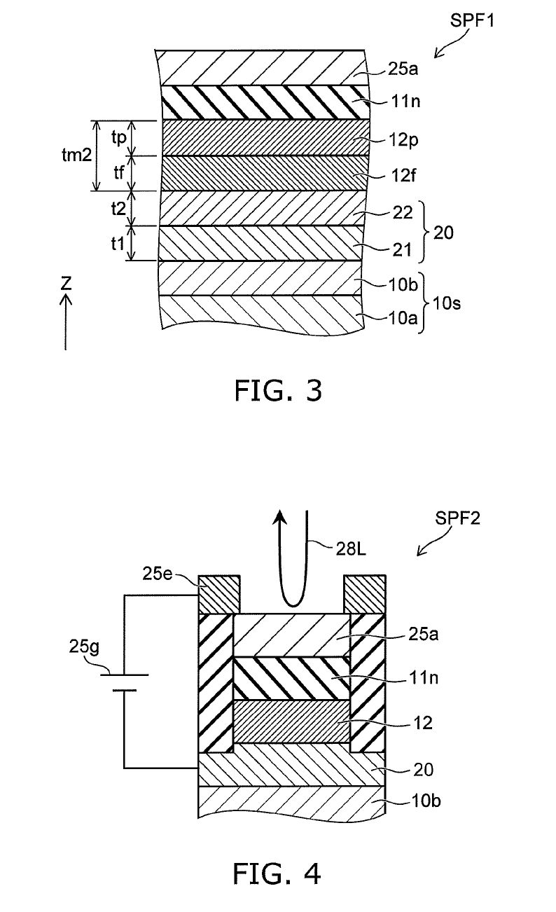

FIG. 3 is a schematic cross-sectional view illustrating the sample of the experiment relating to the magnetic memory device.

As shown in FIG. 3, a substrate 10s is used in a sample SPF1 of the experiment. In the substrate 10s, a thermally-oxidized silicon film 10b is provided on a base body 10a (a silicon substrate). A Ta film (the thickness t1 being 7 nm) that is used to form the first region 21 is provided on the thermally-oxidized silicon film 10b. A Ta₅₀B₅₀ film (the thickness t2 being 3 nm) that is used to form the second region 22 is provided on the first region 21. A magnetic film 12f is provided on the second region 22. The thickness of the magnetic film 12f is set to the thickness tf. A Pt film 12p is provided on the magnetic film 12f. A thickness tp of the Pt film 12p is modified in the experiment. A MgO film (having a thickness of 1.7 nm) that is used to form the first nonmagnetic layer 11n is provided on the Pt film 12p. The Ta film 25a is provided on the MgO film. The thickness of the Ta film 25a is 3 nm.

Multiple types of samples are made in the experiment. In one sample, the magnetic film 12f is an Fe₈₀B₂₀ film. In another sample, the magnetic film 12f is a Co₄₀Fe₄₀B₂₀ film. For these two types, a sample is made in which the Pt film 12p is provided; and a sample is made in which the Pt film 12p is not provided. In the experiment, a sample also is made in which the Ta₅₀B₅₀ film used to form the second region 22 is not provided. In such a case, the magnetic film 12f is formed on the Ta film used to form the first region 21.

These films are formed by sputtering. After forming these films by sputtering, heat treatment (annealing) is performed for 1 hour at 300° C.

Due to the heat treatment, the Pt of the Pt film 12p mixes with the Fe₈₀B₂₀ of the magnetic film 12f. For example, the Pt diffuses inside the magnetic film 12f. Thereby, the second magnetic layer 12 that includes Fe, B, and Pt is obtained.

The Kerr effect of such a sample SPF1 is measured.

FIG. 4 is a schematic cross-sectional view illustrating a sample of the experiment relating to the magnetic memory device.

As shown in FIG. 4, an electrode 25e is further formed on the Ta film 25a of the sample SPF1. The electrode 25e is a Au/Ti stacked film. Thereby, a sample SPF2 for measuring is obtained.

A power supply 25g is connected between the conductive layer 20 and the electrode 25e. A voltage (an electric field) is applied between the conductive layer 20 and the electrode 25e by the power supply 25g.

Laser light 28L is irradiated on the sample SPF2; and the reflected light is detected. The reflected light is detected when changing the applied voltage (electric field). The characteristics of the reflected light are dependent on the Kerr effect of the sample SPF2. Thereby, information relating to the voltage effect of the sample SPF2 is obtained.

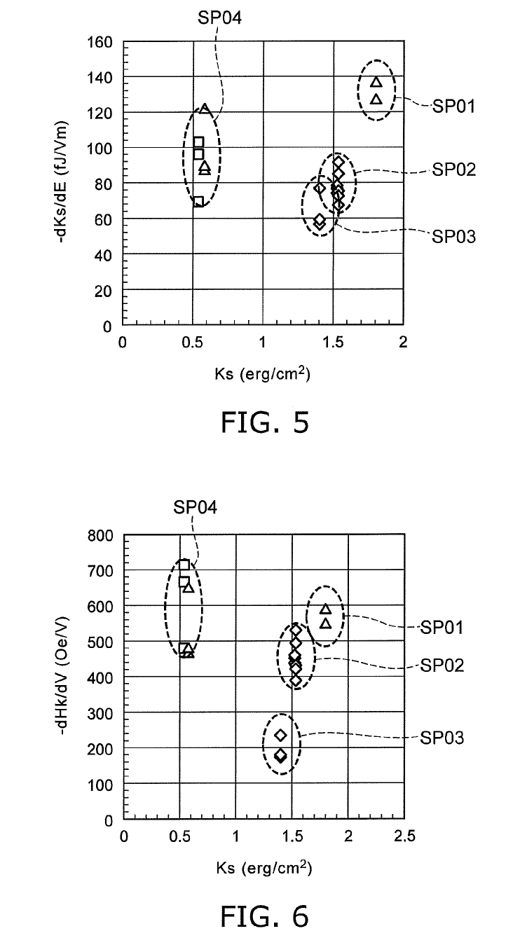

FIG. 5 and FIG. 6 are graphs illustrating experimental results relating to the magnetic memory device.

The measurement results relating to first to fourth samples SP01 to SP04 are shown in these figures.

In the first sample SP01, the second region 22 (the Ta₅₀B₅₀ film) is not provided; the magnetic film 12f is a Co₄₀Fe₄₀B₂₀ film; and the Pt film 12p is not provided. The first sample SP01 has a configuration (prior to the heat treatment) of MgO/Co₄₀Fe₄₀B₂₀/Ta.

In the second sample SP02, the second region 22 (the Ta₅₀B₅₀ film) is not provided; the magnetic film 12f is a Co₄₀Fe₄₀B₂₀ film; and the Pt film 12p is provided. The second sample SP02 has a configuration (prior to the heat treatment) of MgO/Pt/Co₄₀Fe₄₀B₂₀/Ta.

In the third sample SP03, the second region 22 (the Ta₅₀B₅₀ film) is provided; the magnetic film 12f is an Fe₈₀B₂₀ film; and the Pt film 12p is not provided. The third sample

SP03 has a configuration (prior to the heat treatment) of MgO/Fe₈₀B₂₀/Ta₅₀B₅₀/Ta.

In the fourth sample SP04, the second region 22 (the Ta₅₀B₅₀ film) is provided; the magnetic film 12f is an Fe₅₀B₂₀ film; and the Pt film 12p is provided. The fourth sample SP04 has a configuration (prior to the heat treatment) of MgO/Pt/Fe₈₀B₂₀/Ta₅₀B₅₀Ta.

In FIG. 5 and FIG. 6, the horizontal axis is an interface magnetic anisotropy Ks (erg/cm²). The vertical axis of FIG. 5 is a parameter −dKs/dE (fJ/Vm). The parameter −dKs/dE corresponds to the change of the interface magnetic anisotropy Ks with respect to the change of the electric field (the voltage). The parameter −dKs/dE is one of the characteristics relating to the voltage effect. The vertical axis of FIG. 6 is a parameter −dHk/dV (Oe/V). The parameter −dHk/dV corresponds to the change of a perpendicular anisotropic magnetic field Hk with respect to the change of the electric field (the voltage). The parameter −dHk/dV is one of the characteristics relating to the voltage effect.

As shown in FIG. 5, in the case where the second region 22 (the Ta₅₀B₅₀ film) is not provided, the parameter −dKs/dE is about 130 to 140 fJ/Vm for the first sample SP01 in which the Pt film 12p is not provided. Conversely, the parameter −dKs/dE is about 70 to 90 fJ/Vm for the second sample SP02 in which the Pt film 12p is provided. Thus, in the case where the second region 22 (the Ta₅₀B₅₀ film) is not provided, the value of the parameter −dKs/dE is reduced by providing the Pt film 12p.

On the other hand, as shown in FIG. 5, the parameter −dKs/dE is about 60 to 80 fJ/Vm for the third sample SP03 in which the Pt film 12p is not provided. Conversely, the parameter −dKs/dE is about 70 to 120 fJ/Vm for the fourth sample SP04 in which the Pt film 12p is provided. Thus, in the case where the second region 22 (the Ta₅₀B₅₀ film) is provided, the parameter −dKs/dE is increased by providing the Pt film 12p.

Thus, a large difference occurs in the change (the increase or decrease) of the voltage effect due to the existence or absence of Pt between the case where the second region 22 (the Ta₅₀B₅₀ film) is provided and the case where the second region 22 (the Ta₅₀B₅₀ film) is not provided.

As shown in FIG. 6, in the case where the second region 22 (the Ta₅₀B₅₀ film) is not provided, the parameter −dHk/dV is about 550 to 600 Oe/V for the first sample SP01 in which the Pt film 12p is not provided. Conversely, the parameter −dHk/dV is about 400 to 550 Oe/V for the second sample SP02 in which the Pt film 12p is provided. Thus, in the case where the second region 22 (the Ta₅₀B₅₀ film) is not provided, the value of the parameter −dHk/dV is reduced by providing the Pt film 12p.

On the other hand, as shown in FIG. 6, the parameter −dHk/dV is about 170 to 220 Oe/V for the third sample SP03 in which the Pt film 12p is not provided. Conversely, the parameter −dHk/dV is about 480 to 700 Oe/V for the fourth sample SP04 in which the Pt film 12p is provided. Thus, in the case where the second region 22 (the Ta₅₀B₅₀ film) is provided, the parameter −dHk/dV is increased by providing the Pt film 12p. In particular, a conventionally unknown extremely large value of the parameter −dHk/dV is obtained for the fourth sample SP04.

Thus, a large difference occurs in the change of the voltage effect due to the existence or absence of Pt between the case where the second region 22 (the Ta₅₀B₅₀ film) is provided and the case where the second region 22 (the Ta₅₀B₅₀ film) is not provided.

In the case where the second region 22 (the Ta₅₀B₅₀ film) is not provided, the saturation magnetization Ms of the second magnetic layer 12 decreases due to the Pt introduced to the second magnetic layer 12. Conversely, in the case where the second region 22 (the Ta₅₀B₅₀ film) is provided, the saturation magnetization Ms of the second magnetic layer 12 increases due to the Pt introduced to the second magnetic layer 12. For example, it is considered that there is a correlation between the increase of the saturation magnetization Ms and the increase of the absolute value of the voltage effect.

For example, it is considered that the diffusion into the conductive layer 20 of the B inside the second magnetic layer 12 is suppressed by providing the TaB film. The B remains inside the second magnetic layer 12 with a high concentration. By introducing Pt to such a second magnetic layer 12, it is considered that the saturation magnetization Ms increases; and the absolute value of the voltage effect increases in association with the increase of the saturation magnetization Ms.

A configuration (prior to the heat treatment) of MgO/Pt/Fe₈₀B₂₀/Ta₅₀B₅₀/Ta is provided in the fourth sample SP04 recited above. As recited above, a large voltage effect is obtained for a configuration (prior to the heat treatment) of MgO/Pt/CoFeB/Ta₅₀B₅₀/Ta as well.

In the embodiment, the second magnetic layer 12 may include Co in addition to Fe, Pt, and B. The concentration (the composition ratio) of Co in the second magnetic layer 12 is, for example, not less than 10 atm % (atomic percent) and not more than 70 atm %. The concentration (the composition ratio) of Co in the second magnetic layer 12 may be, for example, 30 atm % or less.

The concentration (the composition ratio) of B in the second magnetic layer 12 is, for example, not less than 10 atm % and not more than 30 atm %. The concentration (the composition ratio) of Pt in the second magnetic layer 12 is, for example, not less than 2 atm % and not more than 20 atm %. For example, the concentration (the composition ratio) of Pt in the second magnetic layer 12 may be lower than the concentration (the composition ratio) of B in the second magnetic layer 12.

In the embodiment, existence of Pt inside the second magnetic layer 12 can be observed by, for example, energy dispersive X-ray spectroscopy (EDS) analysis.

An example of the characteristics when modifying the thickness tf of the magnetic film 12f and the thickness tp of the Pt film 12p for the configuration (the configuration of Ta/MgO/Pt/Fe₅₀B₂₀/Ta₅₀B₅₀/Ta prior to the heat treatment) of the sample SPF1 illustrated in FIG. 3 will now be described.

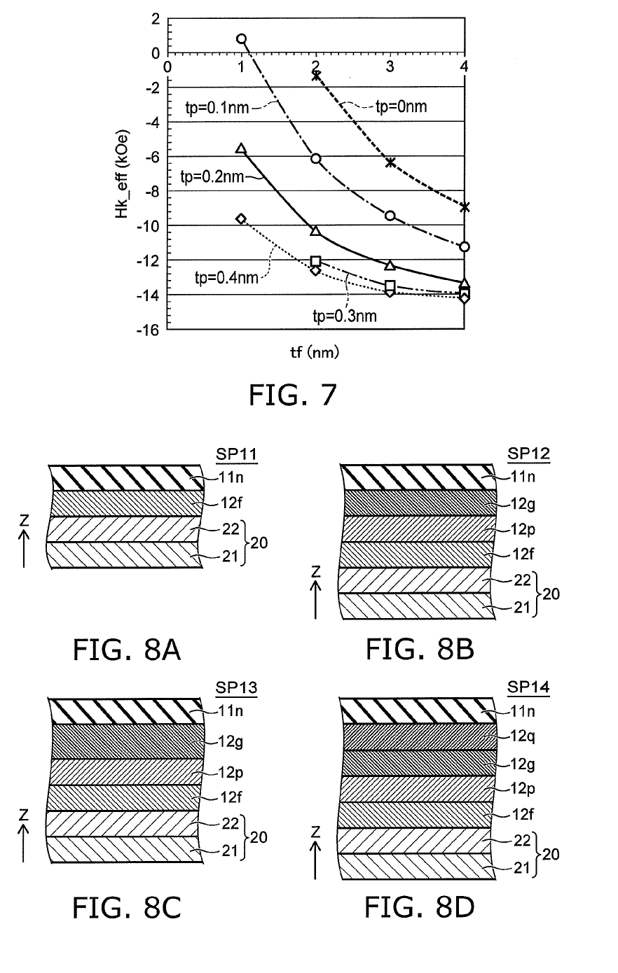

FIG. 7 is a graph illustrating experimental results relating to the magnetic memory device.

The sample shown in FIG. 7 has the configuration (the configuration of Ta/MgO/Pt/Fe₈₀B₂₀/Ta₅₀B₅₀/Ta prior to the heat treatment) of the sample SPF1. The thickness tf of the magnetic film 12f and the thickness tp of the Pt film 12p are different from each other. The thickness tp is displayed as 0 nm for the sample in which the Pt film 12p is not provided. The horizontal axis of FIG. 7 is the thickness tf (nm). The vertical axis is the effective perpendicular anisotropic magnetic field Hk_eff (kOe). The easy magnetization axis is aligned with the film surface perpendicular direction when the perpendicular anisotropic magnetic field Hk_eff is positive.

As shown in FIG. 7, regardless of the thickness tp of the Pt film 12p, the effective perpendicular anisotropic magnetic field Hk_eff increases when the thickness tf of the magnetic film 12f (the Fe₈₀B₂₀ film) is thin. By setting the thickness tf to be thin, the absolute value of the effective perpendicular anisotropic magnetic field Hk_eff can be reduced in the region where the effective perpendicular anisotropic magnetic field Hk_eff is negative.

The effective perpendicular anisotropic magnetic field Hk_eff is relatively high for the sample in which the Pt film 12p is not provided (having the thickness tp of 0 nm). In the case where the thickness tp is 0.1 nm, the effective perpendicular anisotropic magnetic field Hk_eff decreases distinctly compared to the case where the thickness tp is 0 nm. The effective perpendicular anisotropic magnetic field Hk_eff decreases further as the thickness of the thickness tp increases. The effective perpendicular anisotropic magnetic field Hk_eff is substantially the same between when the thickness tp is 0.3 nm and 0.4 nm. Even in the case where the thickness tf is set to be thin, it is difficult for the effective perpendicular anisotropic magnetic field Hk_eff to approach 0.

It can be seen from FIG. 7 that the characteristic is changed greatly by introducing trace Pt to the second magnetic layer 12.

In the embodiment, the sum of the thickness tf of the magnetic film 12f and the thickness tp of the Pt film 12p corresponds to the thickness tm2 of the second magnetic layer 12.

It is possible to set the thickness tf of the magnetic film 12f to be thin down to about 2 atomic layers thick. On the other hand, the thickness tf can be set to be thick if the perpendicular magnetic anisotropy, the voltage effect, and the spin Hall effect can be increased.

It can be seen from FIG. 7 that even if the thickness tp of the Pt film 12p is set to be thin such as 0.1 nm, the effective perpendicular anisotropic magnetic field Hk_eff changes distinctly compared to the case where the Pt film 12p is not provided. For example, it is considered that the magnetic film 12f can be set to be thick for characteristic improvement; accordingly, the thickness tp of the Pt film 12p can be set to be thick up to about 2 atomic layers thick (e.g., about 0.5 nm).

In the embodiment, the thickness tm2 (the length along the first direction) of the second magnetic layer 12 is, for example, not less than 0.6 nm and not more than 6 nm.

In the embodiment, the magnetic dead layer is not formed easily due to the Pt included in the second magnetic layer 12. For example, an efficient memory operation is possible.

An example of experimental results in which the position of the Pt film 12p is modified will now be described.

FIG. 8A to FIG. 8D are schematic cross-sectional views illustrating samples of the experiment relating to the magnetic memory device.

As shown in FIG. 8A, a sample SP11 has a configuration of the first nonmagnetic layer 11n (1.7 nm of MgO)/magnetic film 12f (Co₂₀Fe₆₀B₂₀)/second region 22 (3 nm of Ta₅₀B₅₀)/first region 21 (7 nm of Ta) prior to the heat treatment.

As shown in FIG. 8B, a sample SP12 has a configuration of the first nonmagnetic layer 11n (1.7 nm of MgO)/magnetic film 12g (0.2 nm of Co₂₀Fe₆₀B₂₀)/Pt film 12p (0.2 nm)/magnetic film 12f (Co₂₀Fe₆₀B₂₀)/second region 22 (3 nm of Ta₅₀B₅₀)/first region 21 (7 nm of Ta) prior to the heat treatment.

As shown in FIG. 8C, a sample SP13 has a configuration of the first nonmagnetic layer 11n (1.7 nm of MgO)/magnetic film 12g (0.4 nm of Co₂₀Fe₆₀B₂₀)/Pt film 12p (0.2 nm)/magnetic film 12f (Co₂₀Fe₆₀B₂₀)/second region 22 (3 nm of Ta₅₀B₅₀)/first region 21 (7 nm of Ta) prior to the heat treatment.

As shown in FIG. 8D, a sample SP14 has a configuration of the first nonmagnetic layer 11n (1.7 nm of MgO)/Pt film 12q (0.1 nm)/magnetic film 12g (0.2 nm of Co₂₀Fe₆₀B₂₀)/Pt film 12p (0.1 nm)/magnetic film 12f (Co₂₀Fe₆₀B₂₀)/second region 22 (3 nm of Ta₅₀B₅₀)/first region 21 (7 nm of Ta) prior to the heat treatment.

A sample SP15 is further made. The configuration of the sample SP15 is similar to the configuration of the sample SPF1 illustrated in FIG. 3. The sample SP15 has a configuration of the first nonmagnetic layer 11n (1.7 nm of MgO)/Pt film 12p (0.2 nm)/magnetic film 12f (Co₂₀Fe₆₀B₂₀)/second region 22 (3 nm of Ta₅₀B₅₀)/first region 21 (7 nm of Ta) prior to the heat treatment.

The thickness tf of the magnetic film 12f is modified for the samples SP11 to SP15 recited above.

The Pt film 12p is not provided in the sample SP11. The magnetic film 12f and the Pt film 12p are provided in the sample SP15. In the sample SP12 and the sample SP13, the Pt film 12p is provided between the two magnetic films (the magnetic film 12f and the magnetic film 12g) used to form the second magnetic layer 12. The thickness tp of the Pt film 12p of the sample SP13 is thicker than the thickness tp of the Pt film 12p of the sample SP12. Two Pt films (the Pt film 12p and the Pt film 12q) are provided in the sample SP14. In the samples SP12 to SP15, the total thickness of the films including Pt is 0.2 nm and is constant.

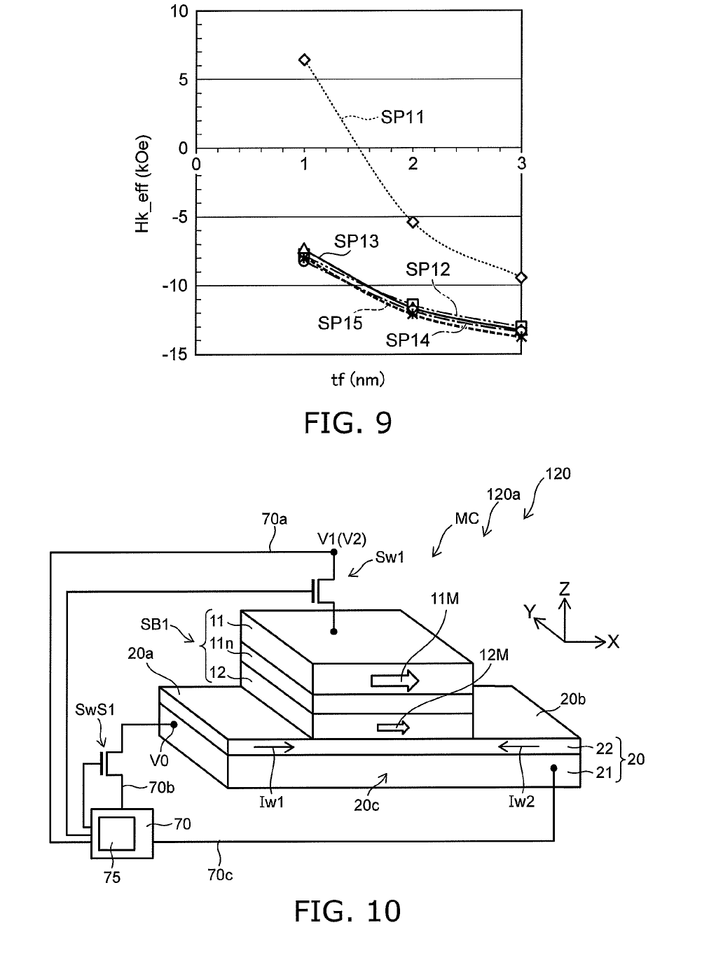

FIG. 9 is a graph illustrating the experimental results relating to the magnetic memory device.

The horizontal axis of FIG. 9 is the thickness tf (nm) of the magnetic film 12f. The vertical axis is the effective perpendicular anisotropic magnetic field Hk_eff (kOe). The easy magnetization axis is aligned with the film surface perpendicular direction when the effective perpendicular anisotropic magnetic field Hk_eff is positive.

In the samples SP11 to SP15 as shown in FIG. 9, the effective perpendicular anisotropic magnetic field Hk_eff increases when the thickness tf of the magnetic film 12f is thin. By setting the thickness tf to be thin, the effective perpendicular anisotropic magnetic field Hk_eff is negative; and the absolute value of the effective perpendicular anisotropic magnetic field Hk_eff can be reduced.

The effective perpendicular anisotropic magnetic field Hk_eff is relatively high for the sample SP11 in which the Pt film 12p is not provided. On the other hand, the effective perpendicular anisotropic magnetic field Hk_eff is low for the samples SP12 to SP15. The effective perpendicular anisotropic magnetic field Hk_eff is substantially the same for the samples SP12 to SP15. It can be seen that the effective perpendicular anisotropic magnetic field Hk_eff is independent of the position of the Pt film in the second magnetic layer 12.

Also, the first magnetic layer 11 (referring to FIG. 2) is formed on each of the samples SP12 to SP15. The TMR (Tunneling Magnetoresistance) ratio and a resistance area product RA are measured for the samples thus obtained. The measured value of the TMR ratio is substantially the same for the samples SP12 to SP15. The resistance area product RA is substantially the same for the samples SP12 to SP15. It can be seen that the magnetoresistance effect substantially is independent of the position of the Pt film in the second magnetic layer 12.

Because the magnetic characteristics, the magnetoresistance, etc., are independent of the position of the Pt film, it is considered that the improvement of the voltage effect recited above is based on the diffusion of Pt into the magnetic film. For example, a large spin-orbit coupling can be expected for Pt.

As recited above, the thickness of the Pt film is constant (0.2 nm) in the samples SP12 to SP15. The characteristic of the effective perpendicular anisotropic magnetic field Hk_eff is substantially the same for these samples. It is considered that the concentration of Pt included in the second magnetic layer 12 is substantially the same for these samples. Accordingly, it is considered that the characteristic of the first stacked body SB1 (the memory cell MC) is substantially determined by the concentration of Pt included in the second magnetic layer 12.

As described above in reference to FIG. 5 and FIG. 6, the improvement of the voltage effect due to the introduction of Pt to the magnetic film is obtained by combining with the second region 22 including boron. This phenomenon is a phenomenon discovered for the first time by the inventor of the application.

In the embodiment, the first metal that is included in the second region 22 may include multiple types of elements. For example, the second region 22 includes TaWB; and the first region 21 includes Ta. Even in the case where the second region 22 includes TaWB, for example, the program current can be reduced. The second region 22 may include, for example, at least one selected from the group consisting of TaWB, TaReB, TaOsB, TaIrB, TaPtB, TaAuB, TaCuB, TaAgB, TaPdB, WReB, WOsB, WIrB, WPtB, WAuB, WCuB, WAgB, WPdB, ReOsB, ReIrB, RePtB, ReAuB, ReCuB, ReAgB, RePdB, OsIrB, OsPtB, OsAuB, OsCuB, OsAgB, OsPdB, IrPtB, IrAuB, IrCuB, IrAgB, IrPdB, PtAuB, PtCuB, PtAgB, PtPdB, AuCuB, AuAgB, AuPdB, CuAgB, CuPdB, and AgPdBO.

In the embodiment, the first metal that is included in the second region 22 may include multiple types of elements. For example, the second region 22 includes TaHfB; and the first region 21 includes Ta. In the case where the second region 22 includes TaHfB, for example, the effective perpendicular anisotropic magnetic field Hk_eff that has a small absolute value is obtained. For example, a high perpendicular magnetic anisotropy is obtained. For example, the program current can be reduced. For example, the first metal may include Hf and at least one selected from the group consisting of Ta, W, Re, Os, Ir, Pt, Au, Cu, Ag, and Pd. For example, the second region 22 may include at least one selected from the group consisting of TaHfB, WHfB, ReHfB, OsHfB, IrHfB, PtHfB, AuHfB, CuHfB, AgHfB, and PdHfB.

Generally, when a heavy metal is used as the conductive layer 20, there is a tendency for a damping constant α of the second magnetic layer 12 provided on the conductive layer 20 to be high. In the embodiment, because the second region 22 includes boron, the concentration of a light element in the second region 22 is high. Thereby, for example, it is considered that the damping constant α of the second magnetic layer 12 can be maintained to be low. In a precessional switching mode, there is a tendency for the current density for the magnetization reversal to decrease as the damping constant a decreases. In the embodiment, for example, the program current can be reduced because the damping constant α can be small.

In the embodiment, at least a portion of the second region 22 may be amorphous.

FIG. 10 is a schematic perspective view illustrating another magnetic memory device according to the first embodiment.

As shown in FIG. 10, the magnetic memory device 120 according to the embodiment also includes the conductive layer 20, the first magnetic layer 11, the second magnetic layer 12, the first nonmagnetic layer 11n, and the controller 70. A magnetic memory element 120a according to the embodiment includes the conductive layer 20, the first magnetic layer 11, the second magnetic layer 12, and the first nonmagnetic layer 11n. The magnetic memory element 120a may be included in the magnetic memory device 120. The direction of the first magnetization 11M of the first magnetic layer 11 in the magnetic memory device 120 (and the magnetic memory element 120a) is different from that of the magnetic memory device 110 (and the magnetic memory element 110a). Otherwise, the configuration of the magnetic memory device 120 is similar to the configuration of the magnetic memory device 110.

In the magnetic memory device 120, the first magnetization 11M of the first magnetic layer 11 is aligned with the second direction (e.g., the X-axis direction). For example, the second magnetization 12M of the second magnetic layer 12 is substantially aligned with the second direction.

In the magnetic memory device 120, for example, a direct switching mode operation is performed. The speed of the magnetization reversal in the direct switching mode is higher than the speed of the magnetization reversal in the precessional switching mode. In the direct switching mode, the magnetization reversal does not follow the precession. Therefore, the magnetization reversal rate is independent of the damping constant α. In the magnetic memory device 120, a high-speed magnetization reversal is obtained.

In the magnetic memory device 120, for example, the length in one direction (the length in the major-axis direction) of the first magnetic layer 11 is longer than the length in one other direction (the minor-axis direction length) of the first magnetic layer 11. For example, the length along the second direction (e.g., the X-axis direction) (the length in the major-axis direction) of the first magnetic layer 11 is longer than the length along the third direction (e.g., the Y-axis direction) (the minor-axis direction length) of the first magnetic layer 11. For example, the first magnetization 11M of the first magnetic layer 11 is easily aligned with the second direction due to the shape anisotropy.

In the magnetic memory device 120, for example, the major-axis direction of the first magnetic layer 11 is aligned with the second direction. The major-axis direction of the first magnetic layer 11 may be tilted with respect to the second direction. For example, the angle (the absolute value of the angle) between the major-axis direction of the first magnetic layer 11 and the second direction (a direction corresponding to the direction of the current flowing through the conductive layer 20) is, for example, not less than 0 degrees but less than 30 degrees. By such a configuration, for example, a high programming speed is obtained.

### Second Embodiment

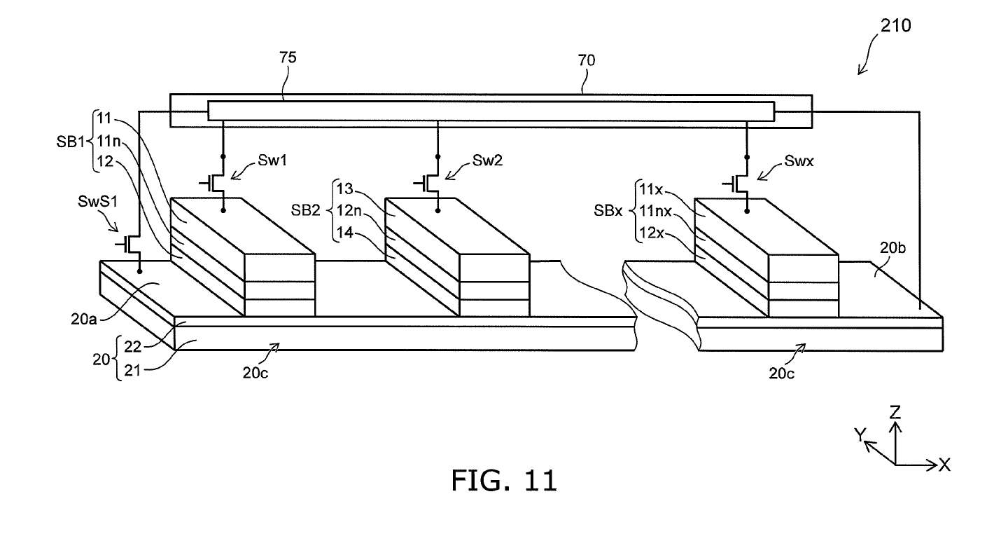

FIG. 11 is a schematic perspective view illustrating a magnetic memory device according to a second embodiment.

As shown in FIG. 11, multiple stacked bodies (the first stacked body SB1, a second stacked body SB2, a stacked body SBx, etc.) are provided in the magnetic memory device 210 according to the embodiment. Multiple switches (the switch Sw1, a switch Sw2, a switch Swx, etc.) also are provided. Otherwise, the configuration of the magnetic memory device 210 is similar to that of the magnetic memory device 110. The multiple stacked bodies are arranged along the conductive layer 20. For example, the second stacked body SB2 includes a third magnetic layer 13, a fourth magnetic layer 14, and a second nonmagnetic layer 12n. The third magnetic layer 13 is separated from a portion of the conductive layer 20 in the first direction (the Z-axis direction). The fourth magnetic layer 14 is provided between the third magnetic layer 13 and the portion of the conductive layer 20. The second nonmagnetic layer 12n is provided between the third magnetic layer 13 and the fourth magnetic layer 14.

For example, the third magnetic layer 13 is separated from the first magnetic layer 11 in the second direction (e.g., the X-axis direction). The fourth magnetic layer 14 is separated from the second magnetic layer 12 in the second direction. The second nonmagnetic layer 12n is separated from the first nonmagnetic layer 11n in the second direction. For example, the stacked body SBx includes a magnetic layer 11x, a magnetic layer 12x, and a nonmagnetic layer 11nx. The magnetic layer 11x is separated from another portion of the conductive layer 20 in the first direction (the Z-axis direction). The magnetic layer 12x is provided between the magnetic layer 11x and the other portion of the conductive layer 20. The nonmagnetic layer 11nx is provided between the magnetic layer 11x and the magnetic layer 12x.

For example, the material and the configuration of the third magnetic layer 13 are the same as the material and the configuration of the first magnetic layer 11. For example, the material and the configuration of the fourth magnetic layer 14 are the same as the material and the configuration of the second magnetic layer 12. For example, the material and the configuration of the second nonmagnetic layer 12n are the same as the material and the configuration of the first nonmagnetic layer 11n.

The multiple stacked bodies function as multiple memory cells MC.

The second region 22 of the conductive layer 20 is provided also between the fourth magnetic layer 14 and the first region 21. The second region 22 of the conductive layer 20 is provided also between the magnetic layer 12x and the first region 21.

The switch Sw1 is electrically connected to the first magnetic layer 11. The switch Sw2 is electrically connected to the third magnetic layer 13. The switch Swx is electrically connected to the magnetic layer 11x. These switches are electrically connected to the control circuit 75 of the controller 70. Any of the multiple stacked bodies are selected by these switches.

In the example of the magnetic memory device 210, the second region 22 extends along the second direction (e.g., the X-axis direction). The second region 22 is provided also in a region corresponding to the region between the multiple stacked bodies.

### Third Embodiment

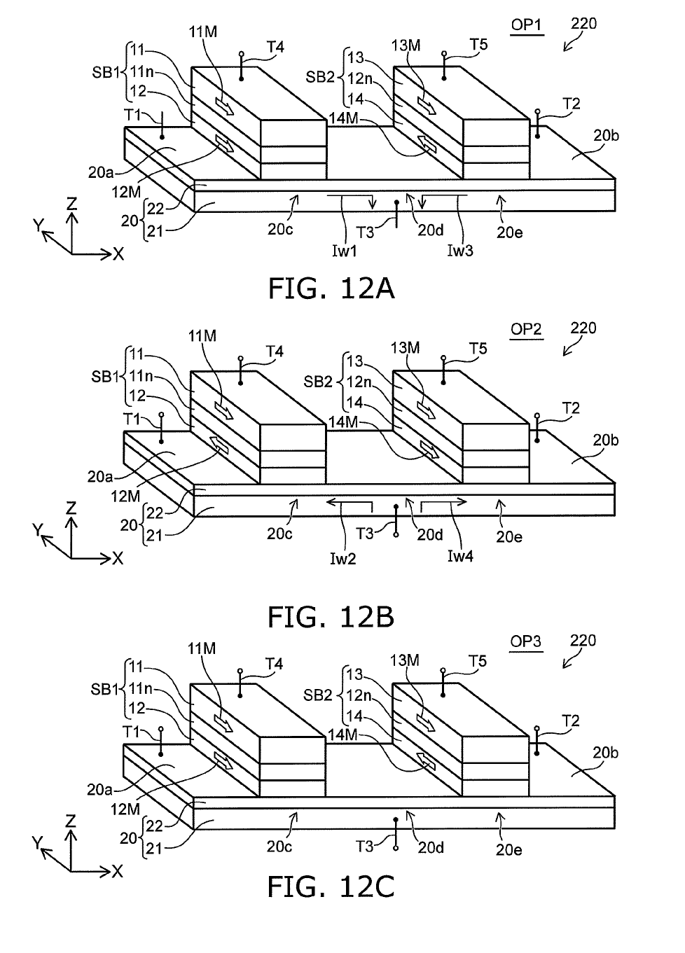

FIG. 12A to FIG. 12C are schematic perspective views illustrating a magnetic memory device according to a third embodiment.

As shown in FIG. 12A, the multiple stacked bodies (the first stacked body SB1 and the second stacked body SB2) are provided in the magnetic memory device 220 according to the embodiment as well. In the magnetic memory device 220, the current that flows in the first stacked body SB1 and the current that flows in the second stacked body SB2 are different from each other.

The first stacked body SB1 overlaps the third portion 20c in the first direction (the Z-axis direction). The second stacked body SB2 overlaps a fifth portion 20e in the first direction. A fourth portion 20d of the conductive layer 20 corresponds to the portion between the first stacked body SB1 and the second stacked body SB2.

For example, a first terminal T1 is electrically connected to the first portion 20a of the conductive layer 20. A second terminal T2 is electrically connected to the second portion 20b. A third terminal T3 is electrically connected to the fourth portion 20d. A fourth terminal T4 is electrically connected to the first magnetic layer 11. A fifth terminal T5 is electrically connected to the third magnetic layer 13.

In one operation OP1 as shown in FIG. 12A, the first current Iw1 flows from the first terminal T1 toward the third terminal T3; and a third current Iw3 flows from the second terminal T2 toward the third terminal T3. The orientation of the current (the first current Iw1) at the position of the first stacked body SB1 is the reverse of the orientation of the current (the third current Iw3) at the position of the second stacked body SB2. In such an operation OP1, the orientation of the spin Hall torque acting on the second magnetic layer 12 of the first stacked body SB1 is the reverse of the orientation of the spin Hall torque acting on the fourth magnetic layer 14 of the second stacked body SB2.

In another operation OP2 shown in FIG. 12B, the second current Iw2 flows from the third terminal T3 toward the first terminal T1; and a fourth current Iw4 flows from the third terminal T3 toward the second terminal T2. The orientation of the current (the second current Iw2) at the position of the first stacked body SB1 is the reverse of the orientation of the current (the fourth current Iw4) at the position of the second stacked body SB2. In such an operation OP2, the orientation of the spin Hall torque acting on the second magnetic layer 12 of the first stacked body SB1 is the reverse of the orientation of the spin Hall torque acting on the fourth magnetic layer 14 of the second stacked body SB2.

As shown in FIG. 12A and FIG. 12B, the orientation of a fourth magnetization 14M of the fourth magnetic layer 14 is the reverse of the orientation of the second magnetization 12M of the second magnetic layer 12. On the other hand, the orientation of a third magnetization 13M of the third magnetic layer 13 is the same as the orientation of the first magnetization 11M of the first magnetic layer 11. Thus, magnetization information that has reverse orientations between the first stacked body SB1 and the second stacked body SB2 is stored. For example, the information (the data) in the case of the operation OP1 corresponds to “1.” For example, the information (the data) in the case of the operation OP2 corresponds to “0.” By such operations, for example, the reading can be faster as described below.

In the operation OP1 and the operation OP2, the second magnetization 12M of the second magnetic layer 12 and the spin current of the electrons (the polarized electrons) flowing through the conductive layer 20 have an interaction. The orientation of the second magnetization 12M and the orientation of the spin of the polarized electrons have a parallel or an antiparallel relationship. The second magnetization 12M of the second magnetic layer 12 precesses and reverses. In the operation OP1 and the operation OP2, the orientation of the fourth magnetization 14M of the fourth magnetic layer 14 and the orientation of the spin of the polarized electrons have a parallel or an antiparallel relationship. The fourth magnetization 14M of the fourth magnetic layer 14 precesses and reverses.

FIG. 12C illustrates a read operation of the magnetic memory device 220.

In the read operation OP3, the potential of the fourth terminal T4 is set to a fourth potential V4. The potential of the fifth terminal T5 is set to a fifth potential V5. The fourth potential V4 is, for example, a ground potential. The potential difference between the fourth potential V4 and the fifth potential V5 is taken as ΔV. Two electrical resistances of each of the multiple stacked bodies are taken as a high resistance Rh and a low resistance RI. The high resistance Rh is higher than the low resistance RI. For example, the resistance corresponds to the high resistance Rh when the first magnetization 11M and the second magnetization 12M are antiparallel. For example, the resistance corresponds to the low resistance RI when the first magnetization 11M and the second magnetization 12M are parallel. For example, the resistance corresponds to the high resistance Rh when the third magnetization 13M and the fourth magnetization 14M are antiparallel. For example, the resistance corresponds to the low resistance RI when the third magnetization 13M and the fourth magnetization 14M are parallel.

For example, in the operation OP1 (the “1” state) illustrated in FIG. 12A, a potential Vr1 of the third terminal T3 is represented by Formula (1).

Vr1=(RI/(RI+Rh))×ΔV (1)

On the other hand, a potential Vr2 of the third terminal T3 in the state of the operation OP2 (the “0” state) illustrated in FIG. 12B is represented by Formula (2).

Vr2=(Rh/(RI+Rh))×ΔV (2)

Accordingly, a potential change ΔVr between the “1” state and the “0” state is represented by Formula (3).

ΔVr=Vr2−Vr1=((Rh−RI)/(RI+Rh))×ΔV (3)

The potential change ΔVr is obtained by measuring the potential of the third terminal T3.

For example, the consumed energy when reading in the read operation OP3 recited above can be reduced compared to the case where a constant current is supplied to the stacked body (the magnetoresistive element) and the voltage (the potential difference) is measured between the two magnetic layers of the magnetoresistive element. In the read operation OP3 recited above, for example, high-speed reading can be performed.

In the operation OP1 and the operation OP2 recited above, the perpendicular magnetic anisotropies of the second magnetic layer 12 and the fourth magnetic layer 14 can be controlled by using the fourth terminal T4 and the fifth terminal T5. Thereby, the program current can be reduced. For example, the program current can be about ½ of the program current in the case where the programming is performed without using the fourth terminal T4 and the fifth terminal T5. For example, the program charge can be reduced. The relationship between the increase or decrease of the perpendicular magnetic anisotropy and the polarity of the voltage applied to the fourth terminal T4 and the fifth terminal T5 is dependent on the materials of the magnetic layers and the conductive layer 20.

### Fourth Embodiment

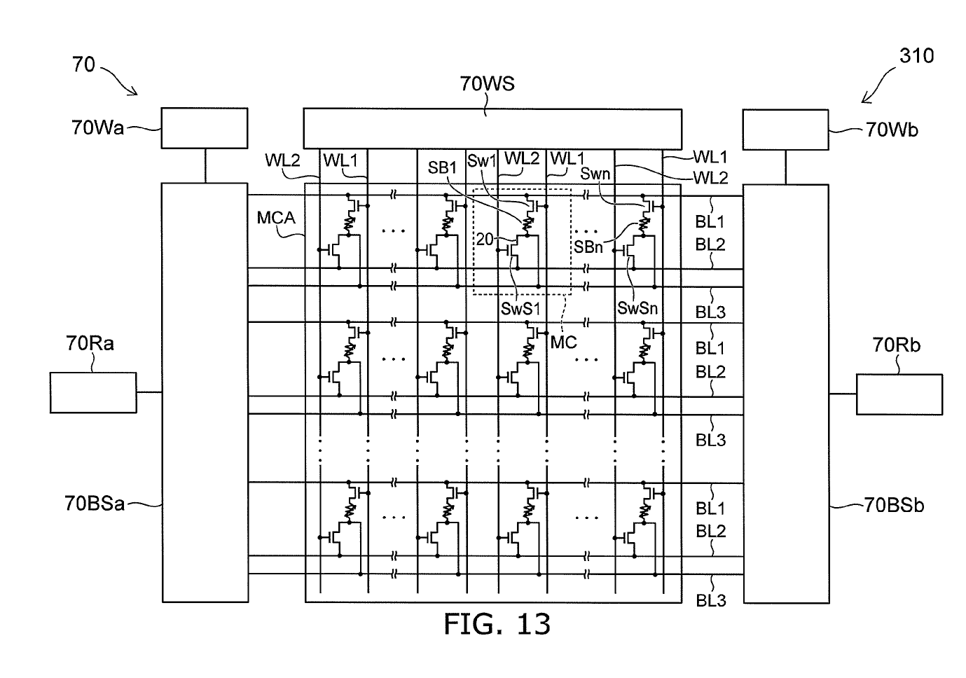

FIG. 13 is a schematic view showing a magnetic memory device according to a fourth embodiment.

As shown in FIG. 13, a memory cell array MCA, multiple first interconnects (e.g., word lines WL1, WL2, etc.), multiple second interconnects (e.g., bit lines BL1, BL2, BL3, etc.), and the controller 70 are provided in the magnetic memory device 310 according to the embodiment. The multiple first interconnects extend in one direction. The multiple second interconnects extend in another one direction. The controller 70 includes a word line selection circuit 70WS, a first bit line selection circuit 70BSa, a second bit line selection circuit 70BSb, a first program circuit 70Wa, a second program circuit 70Wb, a first read circuit 70Ra, and a second read circuit 70Rb. The multiple memory cells MC are arranged in an array configuration in the memory cell array MCA.

For example, the switch Sw1 and the switch SwS1 are provided to correspond to one of the multiple memory cells MC. These switches are considered to be included in the one of the multiple memory cells. These switches may be considered to be included in the controller 70. These switches are, for example, transistors. The one of the multiple memory cells MC includes, for example, a stacked body (e.g., the first stacked body SB1).

As described in reference to FIG. 11, multiple stacked bodies (the first stacked body SB1, the second stacked body SB2, the stacked body SBx, etc.) may be provided for one conductive layer 20. Multiple switches (the switch Sw1, the switch Sw2, the switch Swx, etc.) may be provided respectively for the multiple stacked bodies. In FIG. 13, one stacked body (the stacked body SB1 or the like) and one switch (the switch Sw1 or the like) are drawn to correspond to one conductive layer 20 for easier viewing of the drawing.

As shown in FIG. 13, one end of the first stacked body SB1 is connected to the conductive layer 20. The other end of the first stacked body SB1 is connected to one of the source or the drain of the switch Sw1. The other of the source or the drain of the switch Sw1 is connected to the bit line BL1. The gate of the switch Sw1 is connected to the word line WL1. One end (e.g., the first portion 20a) of the conductive layer 20 is connected to one of the source or the drain of the switch SwS1.

The other end (e.g., the second portion 20b) of the conductive layer 20 is connected to the bit line BL3. The other of the source or the drain of the switch SwS1 is connected to the bit line BL2. The gate of the switch SwS1 is connected to the word line WL2.

A stacked body SBn, a switch Swn, and a switch SwSn are provided for another one of the multiple memory cells MC.

An example of the program operation of the information to the memory cell MC will now be described.

The switch SwS1 of one memory cell MC (the selected memory cell) to which the programming is to be performed is set to the ON state. For example, in the ON state, the word line WL2 that is connected to the gate of one switch SwS1 is set to a high-level potential. The setting of the potential is performed by the word line selection circuit 70WS. The switch SwS1 of another memory cell MC (an unselected memory cell) of the column including the one memory cell MC (the selected memory cell) recited above also is set to the ON state. In one example, the word line WL1 that is connected to the gate of the switch Sw1 inside the memory cell MC (the selected memory cell) and the word lines WL1 and WL2 that correspond to the other columns are set to a low-level potential.

Although one stacked body and one switch Sw1 that correspond to one conductive layer 20 are drawn in FIG. 13, the multiple switches (the switch Sw1, the switch Sw2, the switch Swx, etc.) and the multiple stacked bodies (the stacked body SB1, the second stacked body SB2, the stacked body SBx, etc.) that correspond to one conductive layer 20 are provided as described above. In such a case, for example, the switches that are connected respectively to the multiple stacked bodies are set to the ON state. The select voltage is applied to one of the multiple stacked bodies. On the other hand, the unselect voltage is applied to the other stacked bodies. Programming is performed to the one of the multiple stacked bodies recited above; and the programming is not performed to the other stacked bodies. Selective programming of the multiple stacked bodies is performed.

The bit lines BL2 and BL3 that are connected to the memory cell MC (the selected cell) to which the programming is to be performed are selected. The selection is performed by the first bit line selection circuit 70BSa and the second bit line selection circuit 70BSb. A program current is supplied to the selected bit lines BL2 and BL3. The supply of the program current is performed by the first program circuit 70Wa and the second program circuit 70Wb. The program current flows from one of the first bit line selection circuit 70BSa or the second bit line selection circuit 70BSb toward the other of the first bit line selection circuit 70BSa or the second bit line selection circuit 70BSb. The magnetization direction of the memory layer (the second magnetic layer 12, etc.) of the MTJ element (the first stacked body SB1, etc.) is changeable by the program current. The magnetization direction of the memory layer of the MTJ element is changeable to the reverse direction of that recited above when the program current flows from the other of the first bit line selection circuit 70BSa or the second bit line selection circuit 70BSb toward the one of the first bit line selection circuit 70BSa or the second bit line selection circuit 70BSb. Thus, the programming is performed.

An example of the read operation of the information from the memory cell MC will now be described. The word line WL1 that is connected to the memory cell MC (the selected cell) from which the reading is to be performed is set to the high-level potential. The switch Sw1 inside the memory cell MC (the selected cell) recited above is set to the ON state. At this time, the switches Sw1 of the other memory cells MC (the unselected cells) of the column including the memory cell MC (the selected cell) recited above also are set to the ON state. The word line WL2 that is connected to the gate of the switch SwS1 inside the memory cell MC (the selected cell) recited above and the word lines WL1 and WL2 that correspond to the other columns are set to the low-level potential.

The bit lines BL1 and BL3 that are connected to the memory cell MC (the selected cell) from which the reading is to be performed are selected. The selection is performed by the first bit line selection circuit 70BSa and the second bit line selection circuit 70BSb. The read current is supplied to the selected bit line BL1 and bit line BL3. The supply of the read current is performed by the first read circuit 70Ra and the second read circuit 70Rb. The read current flows from one of the first bit line selection circuit 70BSa or the second bit line selection circuit 70BSb toward the other of the first bit line selection circuit 70BSa or the second bit line selection circuit 70BSb. For example, the voltage between the selected bit lines BL1 and BL3 recited above is sensed by the first read circuit 70Ra and the second read circuit 70Rb. For example, the difference between the magnetization of a reference layer (the first magnetic layer 11) and the magnetization of a memory layer (the second magnetic layer 12) of the MTJ element is detected. The difference includes the orientation of the magnetization being in a mutually-parallel state (having the same orientation) or a mutually-antiparallel state (having the reverse orientation). Thus, the read operation is performed.

According to the embodiment, a magnetic memory device can be provided in which stable operations are possible.

In this specification, the notation of “first material/second material” means that the first material is positioned on the second material. For example, a layer of the first material is formed on a layer of the second material.

In this specification, “perpendicular” and “parallel” include not only strictly perpendicular and strictly parallel but also, for example, the fluctuation due to manufacturing processes, etc.; and it is sufficient to be substantially perpendicular and substantially parallel.

Hereinabove, embodiments of the invention are described with reference to examples. However, the invention is not limited to these examples. For example, one skilled in the art may similarly practice the invention by appropriately selecting specific configurations of components included in the magnetic memory device such as the magnetic layer, the nonmagnetic layer, the conductive layer, the controller, etc., from known art; and such practice is within the scope of the invention to the extent that similar effects can be obtained.

Any two or more components of the examples may be combined within the extent of technical feasibility and are within the scope of the invention to the extent that the spirit of the invention is included.

All magnetic memory devices practicable by an appropriate design modification by one skilled in the art based on the magnetic memory devices described above as the embodiments of the invention also are within the scope of the invention to the extent that the spirit of the invention is included.

Various modifications and alterations within the spirit of the invention will be readily apparent to those skilled in the art; and all such modifications and alterations should be seen as being within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A magnetic memory element, comprising:
a conductive layer;
a first magnetic layer separated from the conductive layer;
a second magnetic layer including iron, platinum, and boron and being provided between the conductive layer and the first magnetic layer; and
a first nonmagnetic layer provided between the first magnetic layer and the second magnetic layer,
the conductive layer including a first region and a second region, the second region including a first metal and boron and being provided between the first region and the second magnetic layer,
the first region not including boron, or a first concentration of boron in the first region being lower than a second concentration of boron in the second region.

2. The element according to claim 1, wherein the first region includes the first metal.

3. The element according to claim 1, wherein the first metal includes at least one selected from the group consisting of Ta, W, Re, Os, Ir, Pt, Au, Cu, Ag, and Pd.

4. The element according to claim 1, wherein the second magnetic layer further includes Co.

5. The element according to claim 1, wherein the second concentration is not less than 10 atomic percent and not more than 50 atomic percent.

6. The element according to claim 1, wherein a concentration of boron in the second magnetic layer is not less than 10 atomic percent and not more than 30 atomic percent.

7. The element according to claim 1, wherein at least a portion of the second region is amorphous.

8. A magnetic memory device, comprising:
the magnetic memory element according to claim 1; and
a controller,
the conductive layer including a first portion, a second portion and a third portion between the first portion and the second portion,
the first magnetic layer being separated from the third portion in a first direction crossing a second direction, the second direction being from the first portion toward the second portion,
the second magnetic layer being provided between the third portion and the first magnetic layer,
the controller being electrically connected to the first portion and the second portion,
the controller being configured to implement
a first operation of supplying a first current to the conductive layer from the first portion toward the second portion, and
a second operation of supplying a second current to the conductive layer from the second portion toward the first portion.

9. The device according to claim 8, wherein
the controller is further electrically connected to the first magnetic layer,
the controller further implements a third operation and a fourth operation,
in the first operation, the controller sets a potential difference between the first portion and the first magnetic layer to a first voltage,
in the second operation, the controller sets the potential difference between the first portion and the first magnetic layer to the first voltage,
in the third operation, the controller sets the potential difference between the first portion and the first magnetic layer to a second voltage and supplies the first current to the conductive layer,
in the fourth operation, the controller sets the potential difference between the first portion and the first magnetic layer to the second voltage and supplies the second current to the conductive layer,
the first voltage is different from the second voltage,
a memory cell including the first magnetic layer, the first nonmagnetic layer, and the second magnetic layer is set to a first memory state by the first operation,
the memory cell is set to a second memory state by the second operation, and
the memory state of the memory cell substantially does not change before and after the third operation, and substantially does not change before and after the fourth operation.

10. The element according to claim 1, wherein the first metal includes Ta.

11. The element according to claim 1, wherein the platinum is dispersed in the second magnetic layer.

12. The element according to claim 1, wherein the boron is dispersed in the second magnetic layer.

13. The element according to claim 1, wherein a length of the first region along a first direction is not less than 1 nanometer and not more than 7 nanometers, the first direction being from the conductive layer toward the first magnetic layer.

14. The element according to claim 1, wherein a length of the second region along a first direction is not less than 1 nanometer and not more than 7 nanometers, the first direction being from the conductive layer toward the first magnetic layer.

15. The element according to claim 1, wherein a length of the second magnetic layer along a first direction is not less than 0.6 nanometers and not more than 6 nanometers, the first direction being from the conductive layer toward the first magnetic layer.

16. The element according to claim 1, wherein a concentration of platinum in the second magnetic layer is not less than 2 atomic percent and not more than 20 atomic percent.

17. The element according to claim 1, wherein a concentration of platinum in the second magnetic layer is lower than a concentration of boron in the second magnetic layer.

18. The element according to claim 1, wherein the first metal includes Hf and at least one selected from the group consisting of Ta, W, Re, Os, Ir, Pt, Au, Cu, Ag, and Pd.

19. The element according to claim 1, wherein
the first region includes Ta, and
the second region includes Ta, Hf, and B.

20. The element according to claim 1, wherein
the first region includes Ta, and
the second region includes Ta, W, and B.
